(19) United States
(12) Patent Application Publication
(10) Pub. No.: US 2025/0359372 A1
(43) Pub. Date: Nov. 20, 2025

(54) Image Sensors and Methods of Fabrication

(71) Applicant: Applied Materials, Inc., Santa Clara, CA (US)

(72) Inventors: Shimin LI, Shanghai (CN); Jian KANG, Shanghai (CN); Zhenmian ZHENG, Shanghai (CN); Shudi MIN, Shanghai (CN); Dalei WANG, Shanghai (CN); Qintao ZHANG, Mt. Kisco, NY (US); Zixiang LI, Beijing (CN)

(21) Appl. No.: 18/950,600

(22) Filed: Nov. 18, 2024

(30) Foreign Application Priority Data
May 17, 2024 (WO) PCT/CN2024/094024

(51) Int. Cl. H01L 27/146

(52) U.S. Cl. CPC H10F 39/8053; H10F 39/024; H10F 39/182; H10F 39/8063

(57) ABSTRACT

Embodiments of image sensors and methods of fabrication are provided herein. In some embodiments, a device includes: a substrate having a dielectric layer disposed atop the substrate; a pillar disposed within the dielectric layer; and a plurality of voids arranged in an array within the dielectric layer, wherein the pillar is disposed between adjacent voids of the plurality of voids. A two-dimensional array of color filters can be disposed atop the substrate having respective voids of the plurality of voids disposed between adjacent color filters and having the pillar disposed between adjacent voids and between diagonally disposed color filters of the array of color filters. A plurality of photoelectric elements can be disposed in the substrate and correspond to and be disposed beneath individual color filters of the array of color filters.

### CROSS-REFERENCE TO RELATED APPLICATIONS

This application claims benefit of International Patent Application No. PCT/CN2024/094024, filed May 17, 2024, and entitled “Image Sensors and Methods of Fabrication,” the contents of which are hereby incorporated by reference in its entirety.

### FIELD

Embodiments of the present disclosure generally relate to image sensors and methods of fabrication of such image sensors.

### BACKGROUND

Image sensors are devices that convert an optical image into an electrical signal. One type of image sensor is a complementary metal oxide semiconductor (CMOS) image sensor (CIS). A CIS includes a plurality of two-dimensionally arranged pixels having a photodiode (PD) that converts incident light into an electrical signal.

As semiconductor devices become more highly integrated, image sensors are also becoming more highly integrated. The inventors have observed that current image sensor designs and methods of fabrication can result in poor light blocking or isolation between adjacent photodiodes, leading to poor performance or pixel failure in the image sensor, including in CIS devices.

Accordingly, the inventors have provided improved image sensor structures and methods of fabrication.

### SUMMARY

Embodiments of image sensors and methods of fabrication are provided herein. In some embodiments, such image sensors can be a complementary metal oxide semiconductor (CMOS) image sensor (CIS). In some embodiments, a device, which can be a partially or completely fabricated image sensor device, can include: a substrate having a dielectric layer disposed atop the substrate; a pillar disposed within the dielectric layer; and a plurality of voids arranged in an array within the dielectric layer, wherein the pillar is disposed between adjacent voids of the plurality of voids. A two-dimensional array of color filters can be disposed atop the substrate having respective voids of the plurality of voids disposed between adjacent color filters and having the pillar disposed between adjacent voids and between diagonally disposed color filters of the array of color filters. A plurality of photoelectric elements can be disposed in the substrate and correspond to and be disposed beneath individual color filters of the array of color filters.

In some embodiments, a device, which can be a partially or completely fabricated image sensor device, can include: a substrate having a dielectric layer disposed atop the substrate; a two-dimensional array of color filters disposed atop the substrate; a plurality of voids arranged in an array within the dielectric layer between adjacent color filters of the array of color filters; and a plurality of pillars disposed within the dielectric layer, wherein one pillar is disposed at respective intersection points of the array of voids. A plurality of photoelectric elements can be disposed in the substrate and correspond to and be disposed beneath individual color filters of the array of color filters.

In some embodiments, a method of fabricating an image sensor includes: forming one or more pillars in a dielectric layer disposed atop a substrate; forming an array of voids aligned with the one or more pillars; and forming a two-dimensional array of color filters having respective voids of the array of voids disposed between adjacent color filters and having the one or more pillars disposed between adjacent voids and between diagonally disposed color filters. Forming one or more pillars can include: forming one or more openings in the dielectric layer; and filling the one or more openings with a pillar material. Forming the array of voids can include: forming at least one air grid trench in the dielectric layer aligned with the one or more pillars; and filling the at least one air grid trench with a dielectric material that pinches off near the top of the at least one air grid trench to form the array of voids. Forming the two-dimensional array of color filters can include: forming a plurality of color filter recesses in the dielectric layer on either side of the array of voids and surrounding the at least one pillar; and forming a color filter within each recess of the plurality of color filter recesses. Forming one or more pillars in the dielectric layer can include forming a plurality of pillars in the dielectric layer, each pillar aligned with and disposed between adjacent voids of the array of voids, and each pillar located between diagonally disposed color filters. The method can further include forming a microlens over each color filter of the array of color filters.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a schematic top view of an image sensor in accordance with embodiments of the present disclosure.

FIG. 2 is a schematic side view of the image sensor depicted in FIG. 1, taken along section line 2-2, in accordance with embodiments of the present disclosure.

FIG. 3 depicts is process flow diagram of a method of fabricating an image sensor in accordance with embodiments of the present disclosure.

FIGS. 4A-4H schematically depict stages of fabrication of an image sensor according to the method of FIG. 3, in accordance with embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of image sensors and methods of fabrication are provided herein. In some embodiments, an image sensor can be a complementary metal oxide semiconductor (CMOS) image sensor (CIS). Image sensor, and CIS, structures in accordance with embodiments of the present disclosure provide an image sensor having an air grid structure separating adjacent pixels of the image sensor and reinforcing pillars provided at cross points, or intersection points, of the air grid. Image sensor structures in accordance with the present disclosure advantageously improve the fabrication process by effectively sealing the air grid structure at the cross points. In addition, the pillar advantageously enhances the optical isolation between adjacent pixels, reducing the optical crosstalk of light at the cross point. In addition, the pillar can advantageously increase the mechanical strength and support of the air grid, avoid tipping, and increase the mechanical reliability of the device.

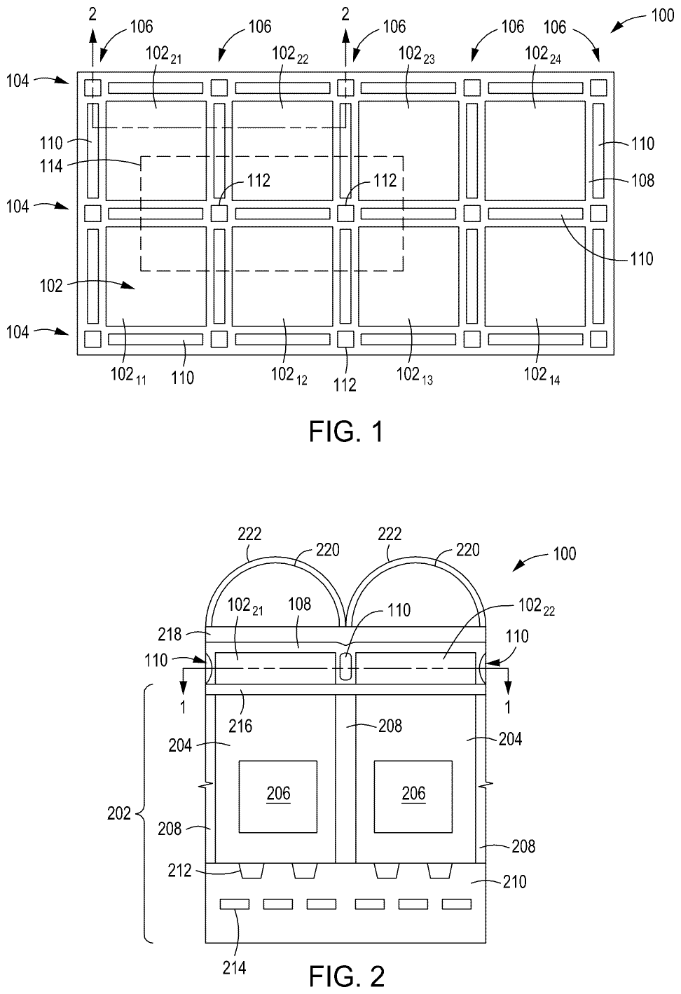

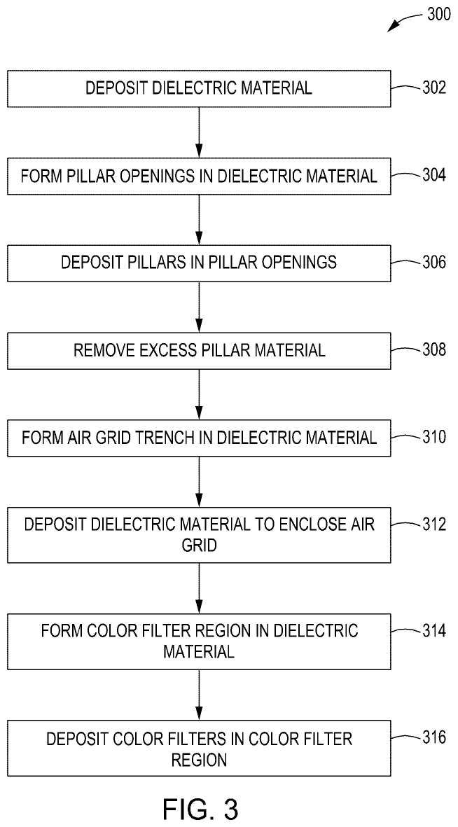

FIG. 1 is a schematic top view of an illustrative CIS structure 100 in accordance with embodiments of the present disclosure. FIG. 2 is a schematic side view of the CIS structure 100 depicted in FIG. 1, taken along section line 2-2. The top view of FIG. 1 is shown taken along section line 1-1 as indicated in FIG. 2. Although discussed below with respect to a CIS, other image sensors having similar structures can also be fabricated in accordance with the teachings disclosed herein.

As shown in FIG. 1, the CIS structure 100 includes a plurality of color filters 102 arranged, for example, in a grid pattern. For example, the plurality of color filters 102 can be arranged in an array having n rows and m columns (e.g., 2 rows and 4 columns illustratively shown in FIG. 1) of color filters 102ₙₘ (e.g., color filters 102₁₁, 102₁₂, 102₁₃, 102₁₄, 102₂₁, 102₂₂, etc.). Each of the color filters 102 may be configured to filter a desired color, such as red, green, blue, yellow, magenta, cyan, or white, and may be arranged as desired for a particular application.

The plurality of color filters 102 are further spaced from each other by intervening rows 104 and columns 106. Spaces directly between adjacent color filters 102ₙₘ are filled with a dielectric layer 108 having an air gap 110 formed therein. In some embodiments, the air gap 110 can extend over all, substantially all, or most of the vertical dimension of the spaces between adjacent color filters 102ₙₘ (as shown in FIG. 2). In some embodiments, the air gap 110 can extend along all, substantially all, or most of the horizontal dimension of the spaces between adjacent color filters 102ₙₘ.

A pillar 112 is formed at the intersections of the rows 104 and columns 106, diagonally between adjacent color filters 102ₙₘ. In some embodiments, the pillar 112 can completely or substantially completely fill the vertical space between adjacent color filters 102ₙₘ. In some embodiments, the pillar 112 has a cross sectional dimension, when viewed from above as in FIG. 1, that prevents a direct line of sight between diagonally adjacent color filters 102ₙₘ (for example, color filters 102₁₁ and 102₂₂).

The inventors have discovered that the air grid and pillar structure between pixels of a CIS device provides several advantages. From an optical perspective, the air grid and pillars can effectively isolate optical crosstalk between color filter films and improve image clarity. With the reduction of device size, through simulation and practical verification, the inventors believe that CIS devices utilizing an air grid and pillar structure in accordance with the teachings disclosed herein advantageously provide good optical isolation between pixels with minimal loss and high quantum efficiency (QE). The pillars provided at the row and column intersections advantageously facilitates filling the intersection point with a thinner dielectric film when forming the air gaps, thus advantageously improving optical isolation between adjacent color filters. Further, the pillars improve mechanical rigidity and strength of the structure, thus advantageously facilitating forming a stable, robust, and reliable CIS device.

As depicted in FIG. 2, the plurality of color filters 102 are formed atop a substrate 202. The substrate 202 includes portions of the CIS structure 100 disposed beneath the plurality of color filters 102. The portions of the CIS structure 100 disposed beneath the plurality of color filters 102 are depicted in an illustrative embodiment and is not intended to be limiting of the disclosure. In general, the substrate 202 and the portions of the CIS structure 100 beneath the plurality of color filters 102 can be configured in any suitable manner used in color filters.

In some embodiments, the substrate 202 can include a semiconductor substrate, such as a silicon-containing wafer, or a non-semiconductor substrate, such as an organic plastic. The substrate 202 includes a first layer 204 that can be, for example, a P- or N-type bulk layer, and can optionally include a P- or N-type epitaxial layer grown thereon.

A plurality of photoelectric elements 206 are disposed in the first layer 204 that correspond to and are disposed beneath individual color filters of the plurality of color filters 102. In some embodiments, one photoelectric element 206 may be disposed beneath a corresponding one of the plurality of color filters 102. In some embodiments, a set of photoelectric elements 206 (e.g., a set of two or more) may be disposed beneath a corresponding one of the plurality of color filters 102. The plurality of photoelectric elements 206 can be, for example, a photodiode, a pinned photodiode, a phototransistor, a photogate, or combinations thereof.

An isolation film 208 can be formed in the first layer 204 between adjacent ones or sets of the photoelectric elements 206. The isolation film 208 can have a constant width (as viewed from the side as in FIG. 2) or isolation film 208 can have a tapered width (as depicted in FIG. 2). Although the width of the isolation film 208 is shown gradually decreasing from a first surface to an opposing second surface of the first layer 204, the width can taper in the opposite direction as well. In addition, the isolation film 208 can extend completely through the first layer 204, or the isolation film 208 can extend only partially through the first layer 204 (e.g., from one of the first surface or the second surface). The isolation film 208 can comprise at least one of, silicon oxide, silicon nitride, silicon oxynitride, or a low dielectric constant material (e.g., having a lower dielectric constant than silicon oxide).

In some embodiments, an insulating layer 210 can be formed below the first layer 204. The insulating layer 210 may comprise one or more of a silicon oxide film, a silicon nitride film, a silicon oxynitride film, a low dielectric constant material, or combinations thereof.

Gate structures 212 corresponding to the various transistor components of the CIS structure 100 can be disposed within the insulating layer 210. Conductive layers 214 corresponding to wiring structures of the CIS structure 100 can be disposed within the insulating layer 210. The conductive layers 214 may comprise any suitable conductive materials, such as one or more of aluminum, copper, tungsten, cobalt, ruthenium, or the like.

In some embodiments, either or both of a lower protective layer 216 and/or an upper protective layer 218 can be disposed on either side of the plurality of color filters 102. For example, in some embodiments, the lower protective layer 216 may be disposed atop the first layer 204 and the isolation film 208 and beneath the plurality of color filters 102. In some embodiments, the upper protective layer 218 may be disposed over the plurality of color filters 102 (e.g., atop the dielectric layer 108). Either of the lower protective layer 216 or the upper protective layer 218 can comprise at least one of, a silicon oxide, silicon nitride, combinations thereof, or the like.

A microlens 220 is disposed atop each of the plurality of color filters 102. Each microlens 220 is configured to collect and direct incident light to the respective color filter 102ₙₘ disposed beneath the given microlens 220. A protective layer 222 can be disposed atop the microlens 220. The protective layer can be, for example, an inorganic material oxide film (e.g., a low temperature oxide, or LTO).

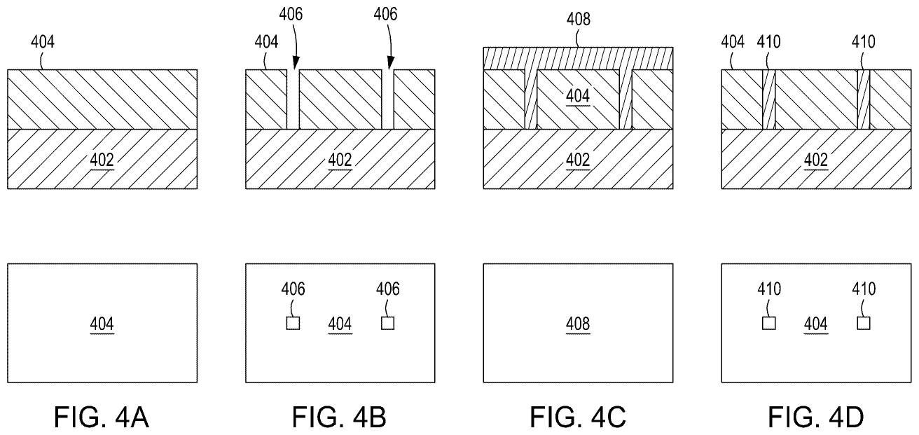

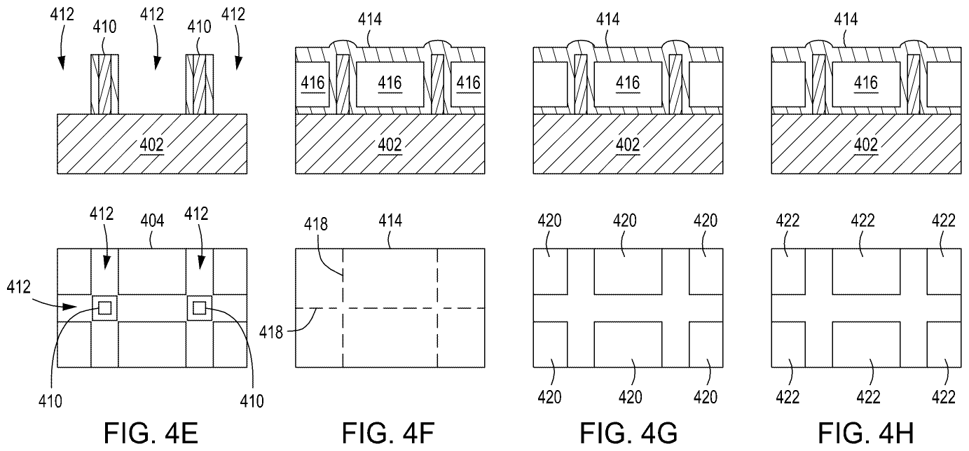

FIG. 3 depicts is process flow diagram of a method 300 of fabricating a CIS device in accordance with embodiments of the present disclosure. FIGS. 4A-4H schematically depict stages of fabrication of a CIS device according to the method of FIG. 3, in accordance with embodiments of the present disclosure. Each of FIGS. 4A-4H include a schematic top view (lower image) and a schematic side view (upper image), taken through a horizontal midline of the top view, during the representative stage of fabrication being illustrated and described. FIGS. 4A-H correspond to region 114 shown in dashed lines in FIG. 1. The method 300 may be used to fabricate a CIS device such as having the CIS structure 100 depicted in FIGS. 1 and 2, or CIS devices having other structural configurations but including an air grid and pillar configuration in accordance with the teachings provided herein.

The method 300 generally begins at block 302, where a dielectric layer 404 is deposited atop a substrate 402 (as depicted in FIG. 4A). The substrate 402 includes portions of the CIS already formed. For example, the substrate 402 may be the substrate 202 described above and may optionally include the lower protective layer 216. The dielectric layer 404 is deposited in a region of the substrate where the CIS is being fabricated, for example, atop a plurality of photoelectric elements 206 or in a region where a plurality of photoelectric elements 206 will later be formed. The dielectric layer 404 can be formed of any suitable dielectric used in the formation of CIS devices, such as silicon oxide, silicon nitride, aluminum oxide, or the like. The silicon oxide can be a low temperature oxide (LTO), or a layer formed by physical enhanced oxidation (PEOX), tetraethoxysilane (TEOS), phenyltriethoxysilane (PTEOS), or the like. The dielectric layer 404 can be deposited to a thickness (e.g., depth) of, for example, 300 nm to 700 nm. The dielectric layer 404 can be deposited at a temperature lower than 400 degrees Celsius.

Next, at block 304 and as depicted in FIG. 4B, one or more pillar openings 406 can be formed in the dielectric layer 404. The pillar openings 406 are formed in locations corresponding to the intersection points of the grid lines extending between adjacent pixel regions of the CIS device being fabricated. The pillar openings 406 can be formed in the dielectric layer 404 in any suitable manner such as by formation of a masking layer (e.g., photoresist or the like) atop the dielectric layer 404 with patterned openings corresponding to the locations of the pillar openings 406 and etching the dielectric layer 404 through the patterned openings of the masking layer. In some embodiments, the pixel regions are arranged in an evenly spaced orthogonal array or grid (e.g., as illustratively depicted in FIG. 1) and, accordingly, the pillar openings 406 are also arranged an evenly spaced pattern corresponding to the intersection points of the orthogonal grid. In some embodiments, the etch process stops at or near the bottom of the dielectric layer 404 (e.g., does not penetrate into the substrate 402).

For example, in embodiments where the substrate 402 includes an array of photoelectric elements 206 corresponding to where the array of color filters 110ₘₙ are to be later formed, the pillar openings 406 can be formed above the intersection points of the grid corresponding to the array of photoelectric elements 206 and/or array of color filters 110ₘₙ. In some embodiments, the pillar openings 406 can be formed in a one-dimensional array (e.g., one row or column) or a two-dimensional array (e.g., two or more rows and two or more columns).

In some embodiments, the pillar openings 406 are formed to a size (e.g., a cross-sectional dimension when viewed from above) of 100 nm to 250 nm across each alley (e.g., row and column to be formed) between adjacent pixel regions (e.g., from 100 by 100 nm to 250 by 250 nm). In some embodiments, the pillar openings 406 are formed completely, or substantially completely, through the dielectric layer 404 (e.g., to the underlying substrate 402). Although shown herein as having a square cross section shape when viewed from above, the pillar openings can be formed having other cross-sectional shapes, such as quadrilateral (e.g., rectangular, square, rhombus, or the like), rounded (e.g., circular, oval, or the like), cross, or other rounded or polygonal shape. The size, such as width/length of a rectangular shape, diameter of a circle, can be varied, and only limited by the mechanical stability of the pillar to be formed. The larger the size of the pillar is, the more space it consumes of the air grid between pixels. In some embodiments, each of the pillar openings 406 have the same cross-sectional shape to form pillars having the same shape. In some embodiments, one or more of the pillar openings 406 has a cross-section shape that is different than one or more others of the pillar openings 406 to form pillars having different shapes. In any of the above embodiments with respect to the shape of the pillar openings 406, the pillar openings 406 can have the same size or have one or more different sizes.

Next at block 306 and as depicted in FIG. 4C, a layer of pillar material 408 is deposited atop the dielectric layer 404 and within the pillar openings 406 to fill the pillar openings 406. The layer of pillar materials 408 completely fills the pillar openings 406. The pillar material 408 can be any process-compatible material having a high refractive index, such as from about 1.9 to about 3.6, or a low refractive index in the visible range, for example from about 1.2 to about 1.9. For example, in some embodiments, the pillar material 408 can be a metal having high refractive index, such as tungsten, aluminum, or the like. In some embodiments, a glue layer can be provided, such as a titanium or titanium nitride layer before metal deposition. Having a pillar formed of such metals advantageously provides excellent light isolation between adjacent pixels of the CIS. In some embodiments, the pillar material 408 can be a dielectric material having a low refractive index, such as silicon oxide (e.g., a low temperature oxide (LTO), PEOX, TEOS, PTEOS, or the like), aluminum oxide, or the like. Having a pillar formed of a low refractive index dielectric material similarly advantageously provides excellent light isolation between adjacent pixels of the CIS. The pillar material 408 can be deposited by any suitable technique, such as atomic layer deposition (ALD), chemical vapor deposition (CVD), plasma-enhanced CVD (PECVD), physical vapor deposition (PVD), or the like.

In some embodiments, the layer of pillar materials 408 can be uniform in composition, e.g., formed from the same material throughout. In some embodiments, layer of pillar materials 408 can be formed of a plurality of sublayers, such that the resultant pillars 410 (described below) can comprise at least a first layer of a first material and a second layer of a second material, different than the first. For example, the first material can be deposited to partially fill the pillar openings 406 and the second material can be deposited to fill the remainder of the pillar openings 406. Alternatively, in some embodiments, alternating layers of the first material and the second material can be repeatedly deposited to form the layer of pillar materials 408 (and the pillars 410) having alternating first and second materials. Alternatively, alternating layers of different materials can be repeatedly deposited to form the layer of pillar materials 408 (and the pillars 410) having alternating layers of materials that can comprise the first material, the second material, and one or more additional materials (e.g., a third material, a fourth material, etc.). In some embodiments, all pillar materials are different than the grid dielectric material 414. In some embodiments, at least one pillar material layer is different than the grid dielectric material 414.

Next at block 308 and as depicted in FIG. 4D, an excess portion of the layer of pillar material 408 is removed from atop the dielectric layer 404 to form pillars 410 disposed in the dielectric layer 404. The resultant pillars 410 have a cross-sectional dimension, when viewed from above, of 100 nm to 250 nm (e.g., the same as the pillar openings 406). The resultant pillars 410 can extend from the substrate 402, or from proximate the substrate 402, to the top of the remaining dielectric layer 404. The excess portion of the layer of pillar material 408 can be removed by any suitable process such as chemical mechanical planarization (CMP), etching, or the like.

Next at block 310 and as depicted in FIG. 4E, one or more air grid trenches 412 are formed in the dielectric layer 404. The air grid trenches 412 are aligned with the pillars 410 and are formed between adjacent pillars 410. The air grid trenches 412 are formed in a one-dimensional array (e.g., one row or column) or a two-dimensional array (e.g., two or more rows and two or more columns) corresponding to the arrangement of the pillars 410. The air grid trenches 412 can be formed in the dielectric layer 404 in any suitable manner such as by formation of a masking layer (e.g., photoresist or the like) atop the dielectric layer 404 with patterned openings corresponding to the locations of the air grid trenches 412 and etching the dielectric layer 404 through the patterned openings of the masking layer.

Next at block 312 and as depicted in FIG. 4F, a grid dielectric material 414 is deposited atop the dielectric layer 404, within the air grid trenches 412, and atop the pillars 410. The grid dielectric material 414 is deposited upon a bottom and sidewalls of the air grid trenches 412 and is deposited in such a manner that material deposited near the top of the sidewalls of the air grid trenches 412 pinches off (as illustrated by dashed lines 418), forming a void 416 within the air grid trenches 412. Accordingly, in some embodiments a void 416 is formed between at least one set of adjacent pillars 410, and in some embodiments, between all sets of adjacent pillars 410. In some embodiments an array of voids 416 are formed having a pillar 410 disposed between adjacent voids of the array of voids 416. In some embodiments, the voids are formed in a location such that an upper portion of the pillar 410 is disposed at a height above the voids 416.

The grid dielectric material 414 can comprise any of the same dielectric materials as the dielectric layer 404, and in some embodiments the grid dielectric material 414 is formed of the same dielectric material as the dielectric layer 404. In some embodiments, the grid dielectric material 414 is aluminum oxide, silicon oxide, or the like. The silicon oxide can be a low temperature oxide (LTO), or a layer formed by physical enhanced oxidation (PEOX), tetraethoxysilane (TEOS), phenyltriethoxysilane (PTEOS), or the like. The grid dielectric material 414 can be deposited by any suitable technique that pinches off the upper portion of the air grid trenches 412 to form voids 416, such as PVD, PECVD, ALD, or the like. Upon completion of deposition the resultant structure includes a fully sealed top surface and a large void underneath.

Next at block 314 and as depicted in FIG. 4G, a plurality of color filter recesses 420 are formed in the grid dielectric material 414 and the dielectric layer 404. The color filter recesses 420 may be arranged in a grid having the air grid trenches 412 disposed between adjacent color filter recesses 420 and having pillars 410 located between diagonally disposed color filter recesses 420. In some embodiments, the color filter recesses 420 may extend completely through the dielectric layer 404 and to the underlying substrate 402. In some embodiments, the color filter recesses 420 may extend only partially through the dielectric layer 404 and not to the underlying substrate 402. The color filter recesses 420 can be formed in the grid dielectric material 414 and the dielectric layer 404 in any suitable manner such as by formation of a masking layer (e.g., photoresist or the like) atop the grid dielectric material 414 with patterned openings corresponding to the locations of the color filter recesses 420 and etching the grid dielectric material 414 and dielectric layer 404 through the patterned openings of the masking layer.

Next at block 316 and as depicted in FIG. 4H, a plurality of color filters 422 can be formed within the color filter recesses 420. The color filters can be formed in any suitable manner and can have different configurations and arrangement (e.g., configured to filter a desired color, such as red, green, blue, yellow, magenta, cyan, or white, as discussed above with respect to FIG. 1). In some embodiments, the color filters 422 can be deposited to a height greater than that of the grid dielectric material 414.

Upon completion of forming the plurality of color filters 422, the method 300 generally ends. However, additional processing continues to complete formation of the CIS structure 100. For example, microlenses (such as microlenses 220 described above with respect to FIG. 2) can be formed atop each color filter 422. Optionally, additional layers can be formed as well, such as an upper protective layer (e.g., upper protective layer 218) disposed between the plurality of color filters 422 and microlenses.

While the foregoing is directed to embodiments of the present disclosure, other and further embodiments of the disclosure may be devised without departing from the basic scope thereof.

1. A device, comprising:
a substrate having a dielectric layer disposed atop the substrate;
a pillar disposed within the dielectric layer; and
a plurality of voids arranged in an array within the dielectric layer, wherein the pillar is disposed between adjacent voids of the plurality of voids.

2. The device of claim 1, wherein the array is an orthogonal array and further comprising at least one additional pillar disposed within the dielectric layer and between adjacent voids of the plurality of voids.

3. The device of claim 1, further comprising:
a two-dimensional array of color filters disposed atop the substrate;
wherein individual voids of the plurality of voids are respectively disposed between adjacent color filters of the array of color filters; and
wherein the pillar is one of a plurality of pillars disposed within the dielectric layer, wherein one pillar is disposed at respective intersection points of the array of voids.

4. The device of claim 3, further comprising:
a plurality of photoelectric elements disposed in the substrate and corresponding to and disposed beneath individual color filters of the array of color filters.

5. The device of claim 1, wherein the pillar comprises one or more of a metal having a high refractive index, or a dielectric material having a low refractive index in the visible range.

6. The device of claim 1, wherein the pillar comprises two or more layers of different materials.

7. The device of claim 1, wherein the pillar has a cross-sectional shape, when viewed from above, that is a quadrilateral, rounded, or a cross.

8. The device of claim 1, wherein the pillar has a cross-sectional dimension, when viewed from above, of 100 nm to 250 nm.

9. The device of claim 1, wherein the pillar extends from the substrate to a height above the plurality of voids.

10. A method of fabricating an image sensor, comprising:
forming one or more pillars in a dielectric layer disposed atop a substrate;
forming an array of voids aligned with the one or more pillars; and
forming a two-dimensional array of color filters having respective voids of the array of voids disposed between adjacent color filters and having the one or more pillars disposed between adjacent voids and between diagonally disposed color filters.

11. The method of claim 10, wherein forming one or more pillars comprises:
forming one or more openings in the dielectric layer; and
filling the one or more openings with a pillar material.

12. The method of claim 10, wherein forming the array of voids comprises:
forming at least one air grid trench in the dielectric layer aligned with the one or more pillars; and
filling the at least one air grid trench with a dielectric material that pinches off near the top of the at least one air grid trench to form the array of voids.

13. The method of claim 10, wherein forming the two-dimensional array of color filters comprises:
forming a plurality of color filter recesses in the dielectric layer on either side of the array of voids and surrounding the one or more pillars; and
forming a color filter within each recess of the plurality of color filter recesses.

14. The method of claim 10, wherein forming one or more pillars in the dielectric layer comprises forming a plurality of pillars in the dielectric layer, each pillar aligned with and disposed between adjacent voids of the array of voids, and each pillar located between diagonally disposed color filters.

15. The method of claim 10, wherein the pillar comprises one or more of a metal having a high refractive index, or a dielectric material having a low refractive index in the visible range.

16. The method of claim 10, wherein the substrate comprises a plurality of photoelectric elements corresponding to and disposed beneath individual color filters of the array of color filters.

17. The method of claim 10, further comprising:
forming a microlens over each color filter of the array of color filters.

18. The method of claim 10:
wherein forming one or more pillars comprises:
forming one or more openings in the dielectric layer; and
filling the one or more openings with a pillar material;
wherein forming the array of voids comprises:
forming at least one air grid trench in the dielectric layer aligned with the one or more pillars; and
filling the at least one air grid trench with a dielectric material that pinches off near the top of the at least one air grid trench to form the array of voids; and
wherein forming the two-dimensional array of color filters comprises:
forming a plurality of color filter recesses in the dielectric layer on either side of the array of voids and surrounding the one or more pillars; and
forming a color filter within each recess of the plurality of color filter recesses.

19. The method of claim 10, wherein forming one or more pillars comprises depositing a first layer of a first material and depositing a second layer of a second material, different than the first material, atop the first layer of the first material to at least partially form each pillar.

20. The method of claim 10, wherein forming one or more pillars comprises forming one or more pillars having a cross-sectional shape, when viewed from above, that is a quadrilateral, rounded, or a cross.
